(19) United States
(12) Patent Application Publication
(10) Pub. No.: US 2025/0224273 A1
(43) Pub. Date: Jul. 10, 2025

(54) OPTICAL DETECTOR AND SPECTROSCOPIC MEASUREMENT DEVICE

(71) Applicant: HAMAMATSU PHOTONICS K.K., Hamamatsu-shi, Shizuoka (JP)

(72) Inventors: Kenichi OHTSUKA, Hamamatsu-shi, Shizuoka (JP); Ikuo ARATA, Hamamatsu-shi, Shizuoka (JP)

(73) Assignee: HAMAMATSU PHOTONICS K.K., Hamamatsu-shi, Shizuoka (JP)

(21) Appl. No.: 18/853,862

(22) PCT Filed: Dec. 19, 2022
(86) PCT No.: PCT/JP2022/046728

§ 371 Date: Oct. 3, 2024

(30) Foreign Application Priority Data
May 27, 2022 (JP) 2022-086933

(51) Int. Cl. G01J 3/28; G01J 3/02; G01J 3/18

(52) U.S. Cl. CPC G01J 3/2803; G01J 3/0205; G01J 3/0262; G01J 3/18

(57) ABSTRACT

An optical detector detects primary light in light to be measured dispersed in an X-axis direction. The optical detector includes a package having an opening, a window closing the opening and allowing the predetermined order of light to transmit, and a light detection element disposed inside the package, including a light receiving region facing the window, and configured to detect the predetermined order of light. The light receiving region includes a plurality of light detection channels arranged in the X-axis direction. The window includes a light transmitting member having a light incident surface and a light exit surface, and a linear variable filter coat formed on one of the light incident surface and the light exit surface, and having a transmitted wavelength changing along the X-axis direction.

### TECHNICAL FIELD

The present disclosure relates to an optical detector and a spectroscopic measurement device.

### BACKGROUND ART

There has been a known spectroscopic measurement device including a light entrance portion that allows light to be measured to be incident thereon, a diffraction grating that disperses light to be measured incident from the light entrance portion, and an optical detector that detects light to be measured dispersed by the diffraction grating. In such a spectroscopic measurement device, when there is an attempt to detect a predetermined order of light (for example, primary light) from dispersed light to be measured, light other than the predetermined order of light (for example, secondary light or higher order light) may be superimposed on the predetermined order of light. Therefore, a filter member for removing light other than the predetermined order of light may be disposed at an upstream stage of the optical detector (for example, see Patent Literature 1).

### CITATION LIST

### Patent Literature

Patent Literature 1: Japanese Unexamined Patent Publication No. 2020-76712

### SUMMARY OF INVENTION

### Technical Problem

However, when the filter member is disposed at an upstream side of the optical detector, there is concern that stray light may increase. For example, there is concern that stray light may increase due to multiple reflections of light to be measured inside the filter member or between the filter member and a window of the optical detector. Suppressing effects of such stray light is extremely important in generating accurate spectral data.

An object of the disclosure is to provide an optical detector and a spectroscopic measurement device capable of detecting a predetermined order of light from dispersed light to be measured.

### Solution to Problem

An optical detector of an aspect of the disclosure is [1] “an optical director for detecting a predetermined order of light in light to be measured dispersed in a predetermined direction, the optical detector including a package having an opening, a window closing the opening and allowing the predetermined order of light to transmit, and a light detection element disposed inside the package, including a light receiving region facing the window, and configured to detect the predetermined order of light, wherein the light receiving region includes a plurality of light detection channels arranged in the predetermined direction, and the window includes a light transmitting member having a light incident surface and a light exit surface, and a linear variable filter coat formed on one of the light incident surface and the light exit surface, and having a transmitted wavelength changing along the predetermined direction”.

In the optical detector described in [1], the window closing the opening of the package includes the light transmitting member and the linear variable filter coat having a transmitted wavelength changing along the predetermined direction in which the light to be measured is dispersed. In this way, it is possible to suppress incidence of light of an order other than the predetermined order on the light detection element for each of the plurality of wavelength components included in the light to be measured. In addition, in the optical detector described in [1], the linear variable filter coat is formed on one of the light incident surface and the light exit surface of the light transmitting member. For example, when a filter coat of a single transmitted wavelength is formed on each of the light incident surface and the light exit surface of the light transmitting member, the light to be measured may be multiple-reflected between the filter coat formed on the light incident surface and the filter coat formed on the light exit surface. However, in the optical detector described in [1], it is possible to suppress generation of stray light due to multiple reflections. As described above, according to the optical detector described in [1], it is possible to detect the predetermined order of light in the dispersed light to be measured.

An optical detector of an aspect of the disclosure may be [2] “the optical detector described in [1], wherein the linear variable filter coat is formed on the light incident surface”. According to the optical detector described in [2], the package and the window can be joined more easily and reliably when compared to the case where the linear variable filter coat is disposed on the light exit surface.

An optical detector of an aspect of the disclosure may be [3] “the optical detector described in [1] or [2], wherein the predetermined order of light is primary light”. The primary light has higher light intensity than that of secondary light. According to the optical detector described in [3], spectral data having an excellent S/N ratio can be generated by causing the linear variable filter coat to function as a higher-order light cut filter for transmitting the primary light in the light to be measured.

An optical detector of an aspect of the disclosure may be [4] “the optical detector described in any one of [1] to [3], wherein the linear variable filter coat is a linear variable long-pass filter coat in which a cut-on wavelength changes along the predetermined direction, or a linear variable bandpass filter coat in which a transmitted wavelength band changes along the predetermined direction”. According to the optical detector described in [4], transmission of the higher-order light is suppressed based on the predetermined order of light, and thus it is possible to suppress appearance of an unnatural peak due to the higher-order light in the spectral data.

An optical detector of an aspect of the disclosure may be [5] “the optical detector described in any one of [1] to [4], wherein the window further includes a reflection reduction layer formed on the other one of the light incident surface and the light exit surface”. According to the optical detector described in [5], it is possible to reduce stray light generated when the light to be measured is multiple-reflected between the light exit surface and the light receiving region.

A spectroscopic measurement device of an aspect of the disclosure is [6] “a spectroscopic measurement device including a light entrance portion allowing light to be measured to be incident thereon, a diffraction grating configured to disperse the light to be measured incident from the light entrance portion, an analyzer configured to generate spectral data of the light to be measured, and the optical detector according to any one of [1] to [5]”.

According to the spectroscopic measurement device described in [6], in the optical detector, it is possible to detect the predetermined order of light in the dispersed light to be measured.

### Advantageous Effects of Invention

According to the disclosure, it is possible to provide an optical detector and a spectroscopic measurement device capable of detecting a predetermined order of light from dispersed light to be measured.

### BRIEF DESCRIPTION OF DRAWINGS

FIG. 1 is a diagram illustrating a configuration of a spectroscopic measurement device of an embodiment.

FIG. 2 is a plan view of an optical detector illustrated in FIG. 1.

FIG. 3 is a cross-sectional view of the optical detector taken along line III-III illustrated in FIG. 2.

FIG. 4 is a diagram illustrating characteristics of a transmitted wavelength of a linear variable filter coat illustrated in FIG. 2.

FIG. 5 is a diagram illustrating a state in which primary light passes through a window illustrated in FIG. 2.

FIG. 6 is a diagram illustrating a state in which stray light is generated in the window illustrated in FIG. 2.

FIG. 7 is a diagram illustrating characteristics of a transmitted wavelength of a filter coat included in a window of a first comparative example.

FIG. 8 is a diagram illustrating a state in which primary light passes through the window illustrated in FIG. 7 and a state in which stray light is generated in the window illustrated in FIG. 7.

FIG. 9 is a diagram illustrating a state in which stray light is generated in a window of a second comparative example.

FIG. 10 is a diagram illustrating a state in which light to be measured passes through a window of a modified example.

### DESCRIPTION OF EMBODIMENTS

Hereinafter, embodiments of the disclosure will be described in detail with reference to the drawings. Note that, in each drawing, the same or corresponding portions are denoted by the same reference numerals, and duplicated description will be omitted.

### [Configuration of Spectroscopic Measurement Device]

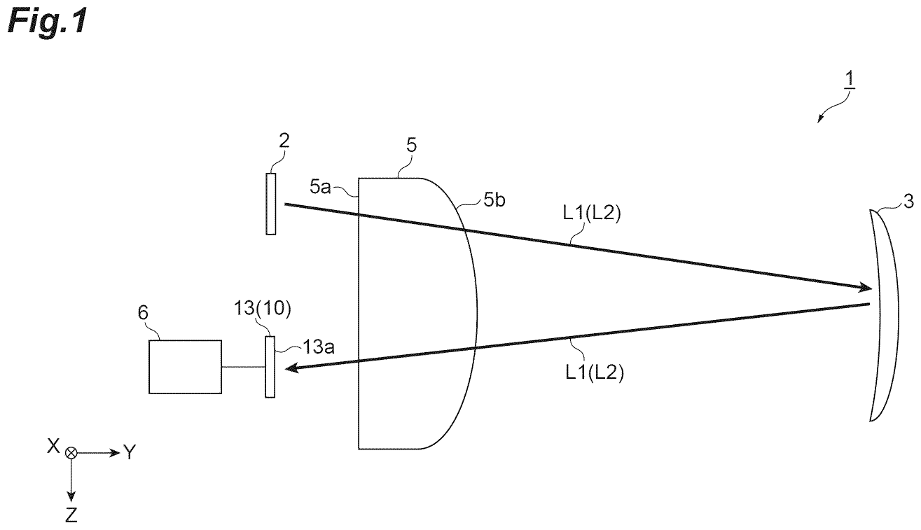

As illustrated in FIG. 1, a spectroscopic measurement device 1 includes a light entrance portion 2, a diffraction grating 3, an optical detector 10, a lens 5, and an analyzer 6. The spectroscopic measurement device 1 is a device that generates spectral data of a plurality of wavelength components L2 included in light to be measured L1 by dispersing the light to be measured L1.

The light entrance portion 2, the diffraction grating 3, and the lens 5 are included in an optical system (so-called Dyson optical system) for guiding the light to be measured L1 to a light receiving region 13a of a light detection element 13 included in the optical detector 10 and forming a spectral image of the plurality of wavelength components L2 of the light to be measured L1 on the light receiving region 13a of the optical detector 10 along a wavelength axis A. In the present embodiment, the diffraction grating 3 is a reflective diffraction grating. The light to be measured L1 is dispersed by the diffraction grating 3 in a direction perpendicular to a direction in which the light to be measured L1 is incident. Here, the direction in which the light to be measured L1 is dispersed (that is, a direction parallel to the wavelength axis A) is referred to as an X-axis direction, a direction perpendicular to the X-axis direction is referred to as a Y-axis direction, and a direction perpendicular to the X-axis direction and the Y-axis direction is referred to as a Z-axis direction. In addition, the optical detector 10 blocks secondary light and detects primary light in the light to be measured L1. The secondary light may appear as an unnatural peak in spectral data. For this reason, it is necessary to block the secondary light in order to extract light of a predetermined order (primary light). Details will be described later.

The light entrance portion 2 is disposed to allow the light to be measured L1 to be incident on the inside of the spectroscopic measurement device 1. The light entrance portion 2 adjusts the amount of incidence of the light to be measured L1. The light entrance portion 2 is, for example, a slit member. When viewed from the Y-axis direction, a slit formed in the slit member opens in a rectangular shape with a short side in the X-axis direction and a long side in the Z-axis direction. When a width of the short side is increased, the amount of incidence of the light to be measured L1 increases, and thus spectral data having less noise and low wavelength resolution is obtained in the analyzer 6. On the other hand, when the width of the short side is decreased, the amount of incidence of the light to be measured L1 decreases, and thus spectral data having improved wavelength resolution and a lot of noise is obtained in the analyzer 6. For example, the light entrance portion 2 may include a slit member and an optical fiber that transmits the light to be measured L1 to the slit member. Alternatively, for example, the light entrance portion 2 may include a slit member and a lens that collects the light to be measured L1 from the outside of the slit member.

The diffraction grating 3 faces the light entrance portion 2 in the Y-axis direction. The diffraction grating 3 is a reflective type, and thus disperses the light to be measured L1 in a direction opposite to the direction in which the light to be measured L1 is incident. The diffraction grating 3 includes a plurality of grating grooves (not illustrated). The plurality of grating grooves extends along the Z-axis direction, which is a direction perpendicular to the alignment direction, while being aligned along the X-axis direction, which is a direction perpendicular to the direction in which the light to be measured L1 is incident. The light to be measured L1 incident on the diffraction grating 3 is dispersed according to the plurality of wavelength components L2 along the X-axis direction, which is a direction in which the plurality of grating grooves is aligned.

The optical detector 10 faces the diffraction grating 3 in the Y-axis direction. The optical detector 10 has the light detection element 13. The light detection element 13 includes the light receiving region 13a that receives the plurality of wavelength components L2. In the optical detector 10, a spectral image having a wavelength axis in the X-axis direction is formed on the light receiving region 13a. The light receiving region 13a has an elongated shape with the X-axis direction as a longitudinal direction, and has a plurality of light detection channels arranged along the X-axis direction (a predetermined direction). That is, a direction in which the plurality of light detection channels is arranged coincides with the direction in which the light to be measured L1 is dispersed. Therefore, each wavelength component L2 is incident on a different position (different light detection channel) at a certain interval along the longitudinal direction of the light receiving region 13a. Each light detection channel includes a plurality of pixels along the Z-axis direction. The optical detector 10 receives a spectral image in the light receiving region 13a over a predetermined exposure time and outputs spectral data S of each wavelength component L2. The light detection element 13 is, for example, a CCD image sensor or a CMOS image sensor formed on a semiconductor substrate. The CCD image sensor may be any of an interline type, a frame transfer type, and a full frame transfer type.

In the present embodiment, the optical detector 10 is disposed at the same position as that of the light entrance portion 2 in the Y-axis direction. The optical detector 10 is disposed at a certain distance from the light entrance portion 2 in the Z-axis direction on a side where the plurality of wavelength components L2 is incident. In other words, the optical detector 10 is offset from the light entrance portion 2 to the side where the plurality of wavelength components L2 is incident along a direction perpendicular to the wavelength axis (the Z-axis direction).

The lens 5 is positioned along the Y-axis direction between the positions of the light incidence portion 2 and the optical detector 4 and the position of the reflective diffraction grating 3. The lens 5 guides the light to be measured L1 incident from the light entrance portion 2 to the diffraction grating 3, and forms a spectral image of the plurality of wavelength components L2 in the light receiving region 13a of the optical detector 10. The lens 5 is a convex lens having a surface 5a and a convex surface 5b opposite to the surface 5a. The surface 5a faces the light entrance portion 2 and the optical detector 10. The surface 5a is a flat surface, a concave surface, or a convex surface. The convex surface 5b faces the diffraction grating 3 and is a surface convexly curved to an opposite side from the surface 5a.

The analyzer 6 generates spectral data S of the light to be measured L1 based on data acquired from the optical detector 10. Content of analysis by the analyzer 6 will be described later. The analyzer 6 includes a storage unit that stores data acquired from the optical detector 10, an analysis result, etc. Further, the analyzer 6 may control the optical detector 4. The analyzer 6 may be, for example, a computer or a tablet terminal equipped with a processor such as a CPU (Central Processing Unit) and a storage medium such as a RAM (Random Access Memory) or a ROM (Read Only Memory). The analyzer 6 may include a microcomputer or an FPGA (Field Programmable Gate Array).

In the spectroscopic measurement device 1 configured as above, the light to be measured L1 incident from the light entrance portion 2 is incident on the surface 5a at a constant incidence angle. The light to be measured L1 incident on the surface 5a is refracted at the surface 5a in accordance with a difference between a refractive index of air and a refractive index of the lens 5, travels inside the lens 5, and exits from the convex surface 5b. The light to be measured L1 exiting from the convex surface 5b is refracted at the convex surface 5b in accordance with the difference between the refractive index of the lens 5 and the refractive index of air, and is guided to the diffraction grating 3 at a downstream stage.

The plurality of wavelength components L2 dispersed by the diffraction grating 3 is incident on the lens 5. The plurality of wavelength components L2 is incident on the lens 5 at a certain incidence angle with respect to the convex surface 5b. The plurality of wavelength components L2 incident on the convex surface 5b is refracted at the convex surface 5b in accordance with a difference between a refractive index of air and a refractive index of the lens 5, travels inside the lens 5, and exits from the surface 5a. The plurality of wavelength components L2 exiting from the surface 5a is refracted at the surface 5a in accordance with the difference between the refractive index of the lens 5 and the refractive index of air, and is imaged on the optical detector 4 at a downstream stage, forming a spectral image in the light receiving region 13a.

### [Configuration of Optical Detector]

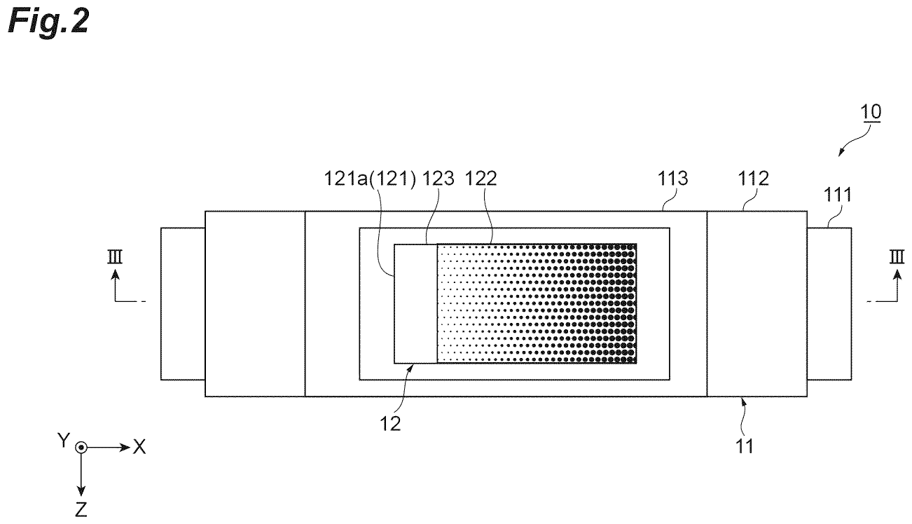

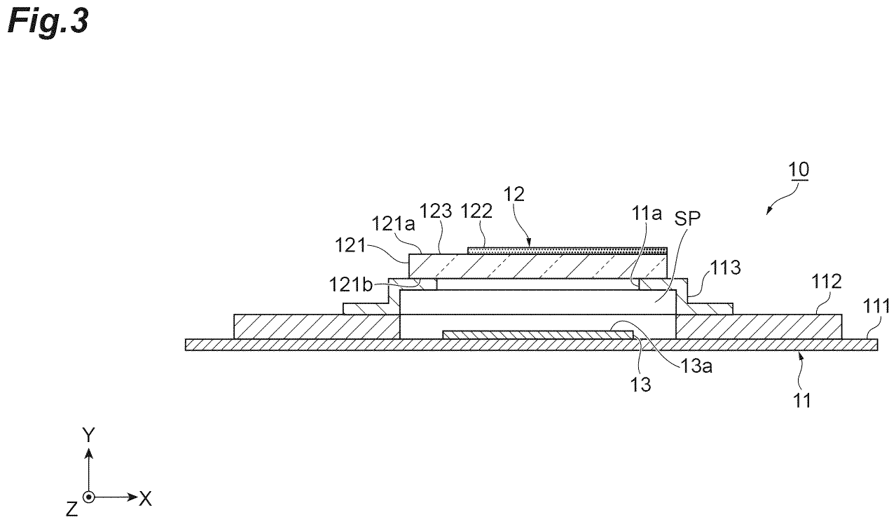

As illustrated in FIGS. 2 and 3, the optical detector 10 further includes a package 11 and a window 12. The package 11 includes a bottom wall 111, a side wall 112, and a top wall 113. The bottom wall 111 has a flat plate shape. The side wall 112 has a frame shape having a rectangular opening. The top wall 113 has a cap shape having a rectangular opening. The side wall 112 is disposed on the bottom wall 111 and joined to the bottom wall 111. The top wall 113 is disposed on the side wall 112 and joined to the side wall 112. As a result, a space SP is formed inside the package 11. As an example, the bottom wall 111, the side wall 112, and the top wall 113 are each made of metal.

The light detection element 13 is disposed on the bottom wall 111. The light detection element 13 is disposed in the space SP inside the package 11. An opening 11a is formed in the package 11. Specifically, the opening 11a is formed in the top wall 113 to face the light detection element 13. When viewed from the Y-axis direction, an inner edge of the top wall 113 forming the opening 11a is smaller than an inner edge of the side wall 112 forming the space SP and an inner edge of the top wall 113 forming the space SP together with the inner edge of the side wall 112. In other words, the top wall 113 has a step shape when viewed from the Z-axis direction so that the area of the inner edge becomes smaller from the inner edge forming the space SP to the inner edge forming the opening 11a. The opening 11a allows the plurality of wavelength components L2 to be incident on the package 11.

The window 12 is disposed on the top wall 113 to close the opening 11a. The window 12 faces the light receiving region 13a of the light detection element 13 disposed in the package 11 in the Y-axis direction. The window 12 includes a light transmitting member 121 and a linear variable filter coat 122. The light transmitting member 121 includes a light incident surface 121a and a light exit surface 121b facing each other in the Y-axis direction. In the present embodiment, the light exit surface 121b of the window 12 is joined to a peripheral portion of the opening 11a in the top wall 113, thereby ensuring airtightness of the space SP. When viewed from the Y-axis direction, the light transmitting member 121 has a rectangular shape having a long side in the X-axis direction and a short side in the Z-axis direction. The light transmitting member 121 is made of, for example, glass, quartz, silicon, germanium, plastic, etc.

The linear variable filter coat 122 is formed on the light incident surface 121a. Similarly to the light transmitting member 121, the linear variable filter coat 122 has a rectangular shape having a long side in the X-axis direction and a short side in the Z-axis direction when viewed from the Y-axis direction. An outer edge of the linear variable filter coat 122 does not completely coincide with an outer edge of the light transmitting member 121, and there is a part 123 where the linear variable filter coat 122 and the light incident surface 121a do not overlap each other. Specifically, a length of the short side of the linear variable filter coat 122 is the same as a length of the short side of the light transmitting member 121, and a length of the long side of the linear variable filter coat 122 is shorter than a length of the long side of the light transmitting member 121. For this reason, in examples of FIGS. 2 and 3, even though one short side of the linear variable filter coat 122 coincides with one short side of the light transmitting member 121, the other short side of the linear variable filter coat 122 is located inside the other short side of the light transmitting member 121. The linear variable filter coat 122 is formed by coating the light incident surface 121a with an insulating multilayer film by deposition, etc., and is continuously formed without gaps. For example, a thickness of the linear variable filter coat 122 gradually increases in a slope shape from one short side along the X-axis direction.

When viewed from the Y-axis direction, the inner edge of the top wall 113 forming the opening 11a is larger than an outer edge of the light detection element 13. Furthermore, the outer edge of the light transmitting member 121 is larger than the inner edge of the top wall 113 forming the opening 11a. In addition, a portion of the outer edge of the light detection element 13 overlaps the part 123 where the linear variable filter coat 122 and the light incident surface 121a do not overlap each other. Specifically, the other short side of the light detection element 13 is located outside the other short side of the linear variable filter coat 122.

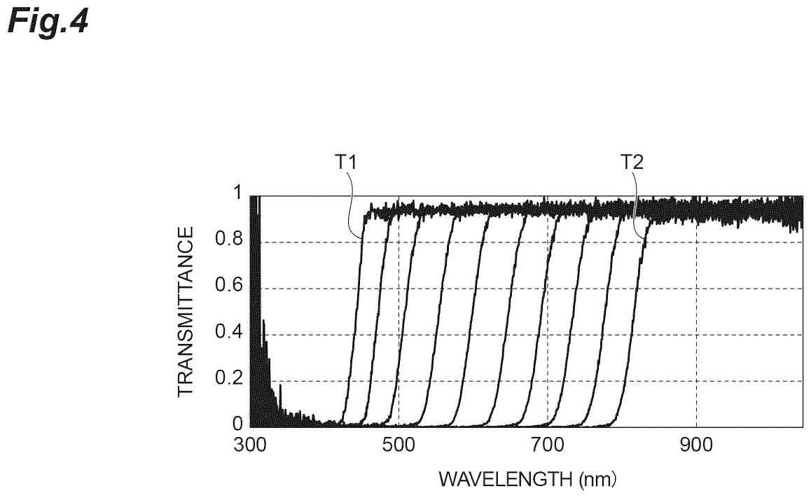

The linear variable filter coat 122 has a transmitted wavelength changing along the X-axis direction (predetermined direction). Specifically, the transmitted wavelength gradually changes to a higher wavelength band with increasing distance from the part 123 where the linear variable filter coat 122 and the light incident surface 121a do not overlap each other. In other words, a blocked wavelength band gradually increases. An example of characteristics of a transmitted wavelength of the linear variable filter coat 122 will be described with reference to FIG. 4 as an example. In a characteristic T1 of a transmitted wavelength of a portion closest to the part 123 where the linear variable filter coat 122 and the light incident surface 121a do not overlap each other, transmittance starts to increase from about 430 nm, the transmittance becomes about 0.9 at about 460 nm, and a cut-on wavelength (wavelength at which the transmittance reaches 50%) is about 450 nm. Meanwhile, in a characteristic T2 of a transmitted wavelength of a portion farthest from the part 123 where the linear variable filter coat 122 and the light incident surface 121a do not overlap each other, transmittance starts to increase from about 780 nm, the transmittance becomes about 0.9 at about 830 nm, and a cut-on wavelength is about 810 nm. The transmitted wavelength of the linear variable filter coat 122 gradually changes to a higher wavelength band between T1 and T2. In the present embodiment, the plurality of wavelength components L2 is incident along a direction in which the transmitted wavelength of the linear variable filter coat 122 changes. Therefore, in each wavelength component L2, primary light is transmitted while secondary light is prevented from being incident on the light detection element 13.

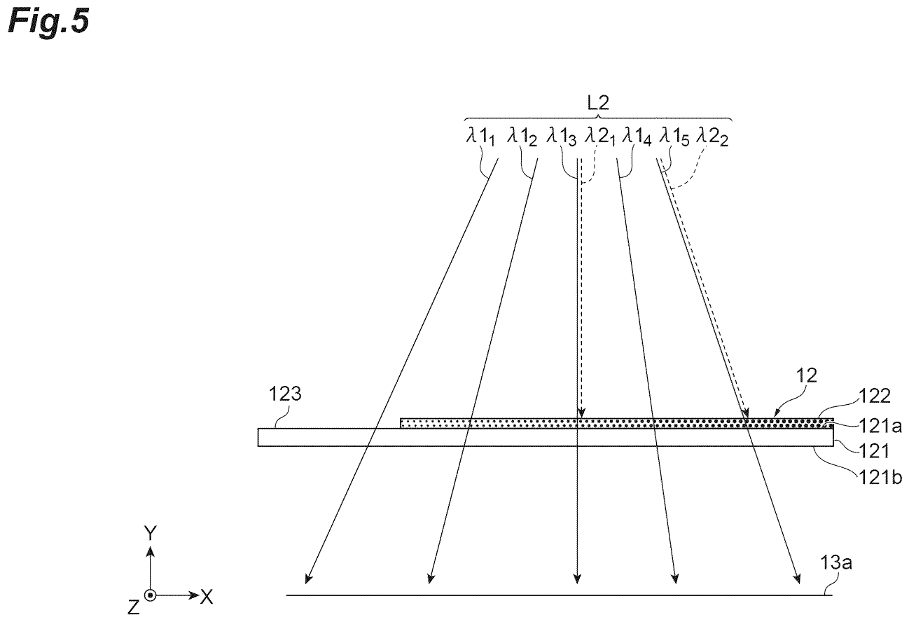

A relationship between each wavelength component L2 and a transmitted wavelength will be described in more detail with reference to FIG. 5. As illustrated in FIG. 5, the plurality of wavelength components L2 includes wavelength components having center wavelengths of λ1₁ to λ1₅. The orders of λ1₁ to λ1₅ are all primary light. Here, for example, λ1₁: 300 nm, λ1₂: 450 nm, λ1₃: 600 nm, λ1₄: 750 nm, and λ1₅: 900 nm. λ1₁ to λ1₅ have increasing diffraction angles in the above order, and are incident on the linear variable filter coat 122 along a direction in which the transmitted wavelength changes in the above order. Here, secondary light of λ1₁ is set to λ2₁, and secondary light of λ1₂ is set to λ2₂. A value of a central wavelength of λ2₁ is 300 nm, which is the same as that of λ1₁, while a diffraction angle of λ2₁ is different from a diffraction angle of λ1₁. The diffraction angle of λ2₁ is the same diffraction angle as that of λ1₃, which has a central wavelength twice that of λ1₁. In other words, λ2₁ is incident at the same incident position as that of λ1₃. Similarly, the secondary light λ2₂ (central wavelength 450 nm) of λ1₂ is incident at the same position as that of λ1₅, which has a central wavelength twice that of λ1₂. The linear variable filter coat 122 functions as a filter that transmits primary light (λ2₁ to λ2₅) of the plurality of wavelength components L2 and blocks the secondary light (λ2₁ and λ2₂). Therefore, the window 12 passes primary light of each wavelength component L2, and the optical detector 10 detects primary light. The linear variable filter coat 122 passes a wavelength component having a wavelength equal to or greater than a central wavelength of primary light, and thus functions as a long-pass filter. In other words, the linear variable filter coat 122 is a linear variable long-pass filter coat whose cut-on wavelength changes along the X-axis direction (predetermined direction). Note that λ1₁ is incident on the part 123 where the linear variable filter coat 122 and the light incident surface 121a do not overlap each other. A reason therefor is that the central wavelength of λ1₁ is 300 nm, and is therefore blocked by the linear variable filter coat 122.

Here, λ1₁ to λ1₅ are incident on the linear variable filter coat 122 to become the corresponding transmitted wavelengths, respectively. For example, in a characteristic of a transmitted wavelength corresponding to an incident position of λ1₃, the primary light λ1₃ (center wavelength 600 nm) is transmitted while the secondary light λ2₁ (center wavelength 300 nm) is blocked. In addition, in a characteristic of a transmitted wavelength corresponding to an incident position of λ1₅, the primary light λ1₅ (center wavelength 900 nm) is transmitted while the secondary light λ2₂ (center wavelength 450 nm) is blocked.

### [Actions and Effects]

In the optical detector 10, the window 12 closing the opening 11a of the package 11 includes the light transmitting member 121 and the linear variable filter coat 122 in which a transmitted wavelength changes along the X-axis direction, which is the direction in which the light to be measured L1 is dispersed. In this way, it is possible to suppress incidence of secondary light (λ2₁ and λ2₂) on the light detection element 13 for each of the plurality of wavelength components L2 included in the light to be measured L1. In addition, in the optical detector 10, the linear variable filter coat 122 is formed on the light incident surface 121a of the light transmitting member 121. For example, when a filter coat of a single transmitted wavelength is formed on each of the light incident surface 121a and the light exit surface 121b of the light transmitting member 121, the light to be measured L1 may be multiple-reflected between the filter coat formed on the light incident surface 121a and the filter coat formed on the light exit surface 121b. However, the optical detector 10 can suppress occurrence of stray light due to multiple reflections. As described above, according to the optical detector 10, it is possible to detect the primary light (λ2₁ and λ2₅) of the dispersed light to be measured L1.

In the optical detector 10, the linear variable filter coat 122 is formed on the light incident surface 121a. In this way, the package 11 and the window 12 can be joined more easily and reliably when compared to the case where the linear variable filter coat 122 is disposed on the light exit surface 121b. In addition, when compared to the case where the linear variable filter coat 122 is disposed on the light exit surface 121b, the light exit surface 121b of the window 12 is more easily joined to the peripheral portion of the opening 11a in the top wall 113, so that airtightness of the space SP can be more easily ensured.

In the optical detector 10, a predetermined order of light is primary light (λ1₁ to λ1₅). The primary light (λ2₁ and λ2₅) has higher light intensity than that of secondary light (λ2₁ and λ2₂). Therefore, according to the optical detector 10, spectral data S having an excellent S/N ratio can be generated by causing the linear variable filter coat 122 to function as a secondary light cut filter for transmitting the primary light (λ2₁ to λ2₅) in the light to be measured L1.

In the optical detector 10, the linear variable filter coat 122 is a linear variable long-pass filter coat whose cut-on wavelength changes along the X-axis direction. In this way, transmission of the secondary light (λ2₁ and λ2₂) is suppressed based on the primary light (λ2₁ and λ2₅), and thus it is possible to suppress appearance of an unnatural peak due to the secondary light (λ2₁ and λ2₂) in the spectral data S.

According to the spectroscopic measurement device 1, the optical detector 10 can detect the primary light (λ2₁ to λ2₅) in the dispersed light to be measured L1.

### Comparative Examples

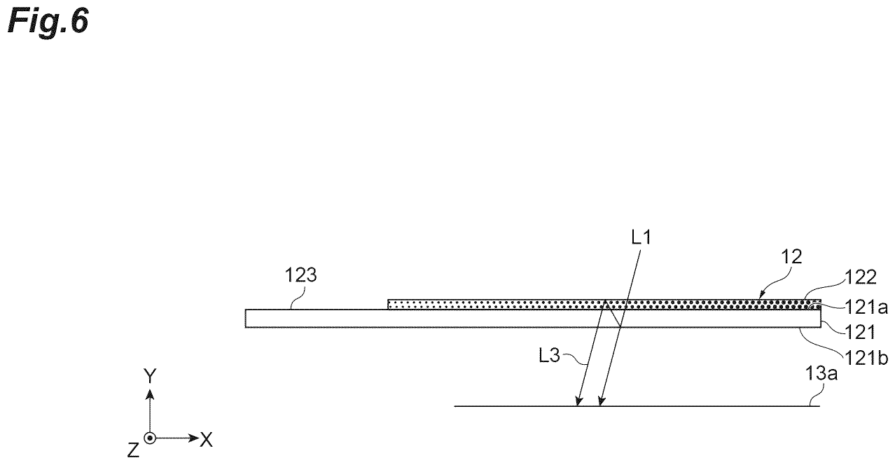

As illustrated in FIG. 6, a part of the light to be measured L1 incident on the window 12 may be reflected by the light exit surface 121b of the light transmitting member 121, and then reflected by a surface of the linear variable filter coat 122, resulting in stray light L3. The stray light L3 may appear as an unnatural peak in the spectral data, and thus needs to be suppressed. However, when compared to a comparative example described later, the linear variable filter coat 122 can reduce a cause of the stray light L3.

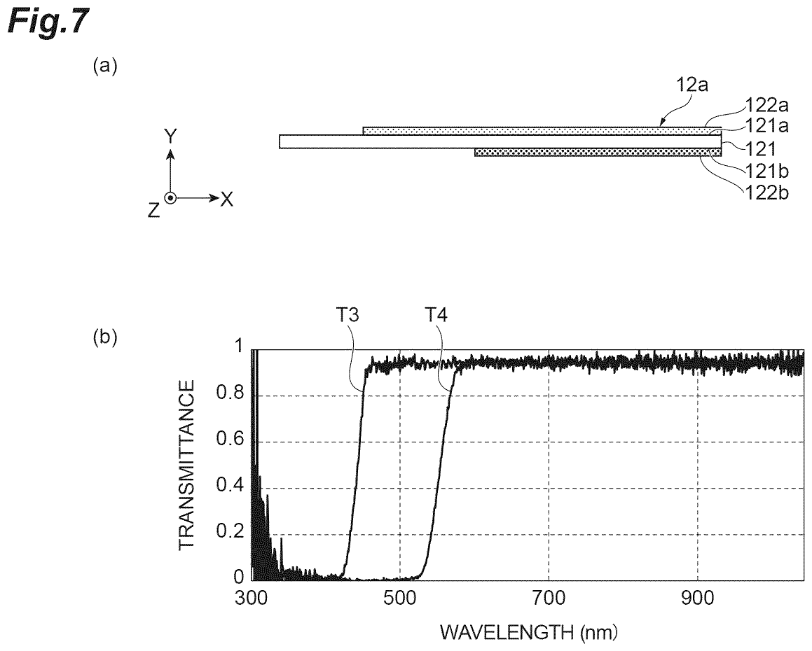

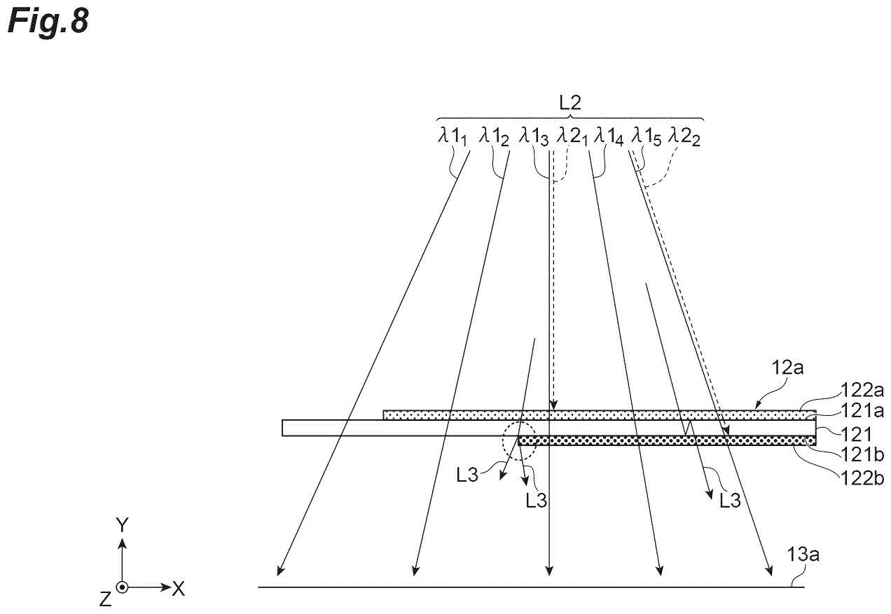

A window 12a of a first comparative example will be described with reference to FIGS. 7 and 8. As illustrated in FIG. 7(a), in the window 12a, a filter coat 122a is formed on the light incident surface 121a of the light transmitting member 121, and a filter coat 122b is formed on the light exit surface 121b of the light transmitting member 121. When viewed from the Y-axis direction, each of the filter coat 122a and the filter coat 122b has a rectangular shape having a long side in the X-axis direction and a short side in the Z-axis direction. One short side of the filter coat 122a coincides with one short side of the light transmitting member 121 and one short side of the filter coat 122b. The other short side of the filter coat 122a is located inside the other short side of the light transmitting member 121 and outside the other short side of the filter coat 122b. As illustrated in FIG. 7(b), the filter coat 122a and the filter coat 122b each have a different single transmitted wavelength characteristic. An example of the transmitted wavelength characteristic is as follows. In a characteristic T3 of a transmitted wavelength of the filter coat 122a, transmittance starts to increase from about 420 nm, and the transmittance becomes about 0.9 at about 450 nm. A cut-on wavelength is about 440 nm. Meanwhile, in a characteristic T4 of a transmitted wavelength of the filter coat 122b, transmittance starts to increase from about 520 nm, and the transmittance becomes about 0.9 at about 570 nm. A cut-on wavelength is about 550 nm.

A relationship between each wavelength component L2 and a transmitted wavelength will be described in more detail with reference to FIG. 8. A central wavelength of each of λ2₁ to λ2₅ is similar to that in the embodiment. Similarly to the linear variable filter coat 122, each of the filter coat 122a and the filter coat 122b functions as a filter that transmits the primary light (λ2₁ to λ2₅) of the plurality of wavelength components L2 and blocks the secondary light (λ2₁ and λ2₂). For example, λ1₃ passes through the filter coats 122a and 122b, while λ2₁ is blocked by the filter coat 122a. Here, when the filter coat 122a and the filter coat 122b are used, stray light occurs due to various factors. For example, since the other short side of the filter coat 122b is located inside the other short side of the filter coat 122a, the other short side of the filter coat 122b serves as an end surface when viewed from the Z-axis direction. Any of the wavelength components L2 may be scattered at the end surface of the filter coat 122b and cause the stray light L3. Furthermore, any of the wavelength components L2 may be multiple-reflected between the filter coat 122a and the filter coat 122b and cause the stray light L3. In either case, the stray light L3 is not generated when the linear variable filter coat 122 of the embodiment is used as a part of the window 12. Therefore, in the optical detector 10 of the embodiment, it is possible to suppress incidence of the stray light L3 caused by scattering or multiple reflections on the light detection element 13.

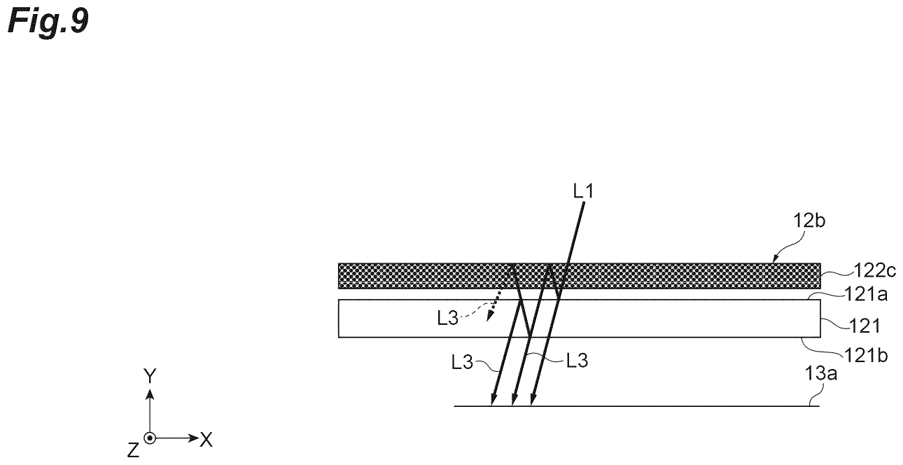

Next, a window 12b of a second comparative example will be described with reference to FIG. 9. In the window 12b, a filter coat is not formed on the light transmitting member 121, and filter member 122c thicker than the filter coat is disposed on the light incident surface 121a. The filter member 122c and the light transmitting member 121 are collectively referred to as the window 12b. In this case, the stray light L3 is generated due to various factors. For example, the stray light L3 is generated by multiple reflections inside the filter member 122c, or multiple reflections between the filter member 122c and the light incident surface 121a or the light exit surface 121b. In other words, the number of places where stray light can be generated is significantly increased when compared to the linear variable filter coat 122 of the embodiment.

### Modified Example

The disclosure is not limited to the above-mentioned embodiment. The linear variable filter coat 122 may be a linear variable bandpass filter coat in which a transmitted wavelength band changes along the X-axis direction. In this case, the linear variable filter coat 122 functions as a filter that transmits only a certain range of wavelength components including a central wavelength of primary light for each wavelength component L2. In this way, transmission of secondary light is suppressed based on primary light, so that it is possible to suppress appearance of an unnatural peak caused by secondary light in the spectral data S. In addition, the spectroscopic measurement device 1 of the embodiment is a Dyson optical system including the light entrance portion 2, the diffraction grating 3, the optical detector 10, the lens 5, and the analyzer 6. However, the spectroscopic measurement device 1 may be a different optical system. For example, the spectroscopic measurement device 1 may be a Czerny-Turner optical system. Furthermore, when an optical system different from the Dyson optical system is adopted, the diffraction grating 3 may be a transmissive diffraction grating. In addition, the linear variable filter coat 122 may be formed on the light exit surface 121b. In addition, light blocked by the linear variable filter coat 122 is not limited to secondary light. For example, it is possible to block higher-order light (such as third-order light or fourth-order light), block diffracted light of negative orders, or block reflected light (zeroth-order light). Meanwhile, the linear variable filter coat 122 may transmit light of orders other than the first order (for example, light of the above-mentioned orders) as the predetermined order and block primary light.

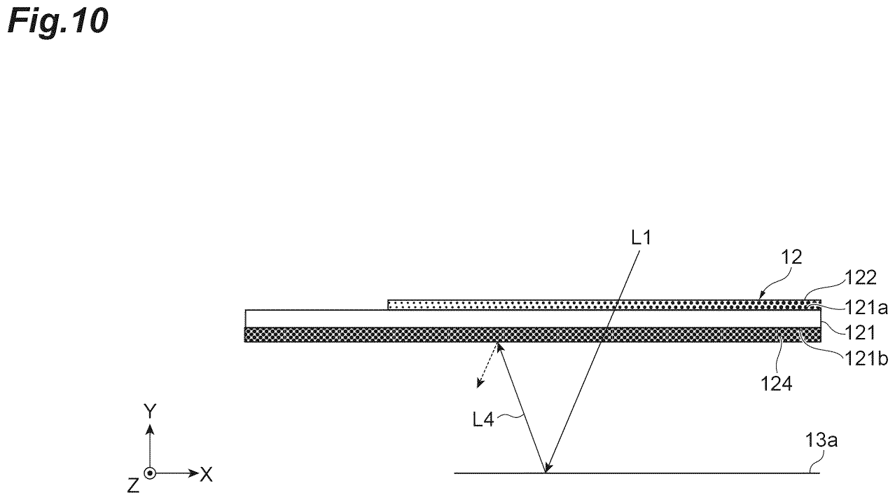

As illustrated in FIG. 10, the window 12 may further include a reflection reduction layer 124. The window 12 illustrated in FIG. 10 includes the light transmitting member 121, the linear variable filter coat 122, and the reflection reduction layer 124. In the window 12 illustrated in FIG. 10, the linear variable filter coat 122 is formed on the light incident surface 121a of the light transmitting member 121, and the reflection reduction layer 124 is formed on the light exit surface 121b of the light transmitting member 121. For example, the reflection reduction layer 124 is formed by a single layer of magnesium fluoride (MgF₂), silicon dioxide (SiO₂), titanium oxide (TiO₂), zirconia (ZrO₂), or tantalum pentoxide (Ta₂O₅), or a laminate of a plurality of these substances.

In the window 12 illustrated in FIG. 10, the reflection reduction layer 124 is formed on the entire surface of the light exit surface 121b. In other words, when viewed from the Y-axis direction, an outer edge of the reflection reduction layer 124 coincides with the outer edge of the light transmitting member 121. However, the reflection reduction layer 124 may be formed on a part of the light exit surface 121b. For example, the reflection reduction layer 124 may be formed to overlap at least the linear variable filter coat 122 when viewed from the Y-axis direction. In this case, the outer edge of the reflection reduction layer 124 may coincide with the outer edge of the linear variable filter coat 122 when viewed from the Y-axis direction.

The reflection reduction layer 124 is, for example, an AR coat (Anti-Reflection coating). In this case, when reflected light L4 of the light to be measured L1 reflected by the light receiving region 13a is incident on the reflection reduction layer 124, the reflected light L4 is canceled out by optical interference in the reflection reduction layer 124. For example, in the reflection reduction layer 124, the reflected light L4 is canceled out by interference between light reflected by a surface of the reflection reduction layer 124 on the light transmitting member 121 side and light reflected by a surface of the reflection reduction layer 124 on the light receiving region 13a side. When the reflection reduction layer 124 is not formed, the reflected light L4 may become stray light by being reflected at the light exit surface 121b of the light transmitting member 121 and multiple-reflected between the light exit surface 121b and the light receiving region 13a. In the window 12 illustrated in FIG. 10, the reflection reduction layer 124 is formed on the light exit surface 121b, thereby making it possible to reduce stray light caused by the reflected light L4.

The reflection reduction layer 124 is not limited to the AR coat. For example, the reflection reduction layer 124 may be a multilayer film. In this case, a refractive index of the reflection reduction layer 124 changes for each layer. For example, the refractive index of the reflection reduction layer 124 may change stepwise from a refractive index of a gap between the reflection reduction layer 124 and the light receiving region 13a (refractive index of air) to a refractive index of the light transmitting member 121. In this case, the reflected light L4 is not reflected at the light exit surface 121b of the light transmitting member 121, and is emitted to the outside through the light transmitting member 121 and the linear variable filter coat 122.

The linear variable filter coat 122 may be formed on the light exit surface 121b of the light transmitting member 121, and the reflection reduction layer 124 may be formed on the light incident surface 121a of the light transmitting member 121. In this case, for example, in the reflection reduction layer 124, the reflected light L4 is canceled out by interference between light reflected at a surface of the reflection reduction layer 124 on the light transmitting member 121 side and light reflected at a surface of the reflection reduction layer 124 opposite the light transmitting member 121.

Reference Signs List

1: spectroscopic measurement device, 2: light entrance portion, 3:
diffraction grating, 10: optical detector, 6: analyzer, 11: package, 11a:
opening, 12: window, 13: light detection element, 13a: light receiving
region, 121: light transmitting member, 121a: light incident surface, 121b:
light exit surface, 122: linear variable filter coat, 124: reflection reduction
layer, L1: light to be measured, S: spectral data.

1. An optical detector for detecting a predetermined order of light in light to be measured dispersed in a predetermined direction, the optical detector comprising:
a package having an opening;
a window closing the opening and allowing the predetermined order of light to transmit; and
a light detection element disposed inside the package, including a light receiving region facing the window, and configured to detect the predetermined order of light, wherein:
the light receiving region includes a plurality of light detection channels arranged in the predetermined direction, and
the window includes:
a light transmitting member having a light incident surface and a light exit surface; and
a linear variable filter coat formed on one of the light incident surface and the light exit surface, and having a transmitted wavelength changing along the predetermined direction.

2. The optical detector according to claim 1, wherein the linear variable filter coat is formed on the light incident surface.

3. The optical detector according to claim 1, wherein the predetermined order of light is primary light.

4. The optical detector according to claim 1, wherein the linear variable filter coat is a linear variable long-pass filter coat in which a cut-on wavelength changes along the predetermined direction, or a linear variable bandpass filter coat in which a transmitted wavelength band changes along the predetermined direction.

5. The optical detector according to claim 1, wherein the window further includes a reflection reduction layer formed on the other one of the light incident surface and the light exit surface.

6. A spectroscopic measurement device comprising:
a light entrance portion allowing light to be measured to be incident thereon;
a diffraction grating configured to disperse the light to be measured incident from the light entrance portion;
an analyzer configured to generate spectral data of the light to be measured; and
the optical detector according to claim 1.
